(19) United States
(12) Patent Application Publication
(10) Pub. No.: US 2015/0362546 A1
(43) Pub. Date: Dec. 17, 2015

(54) PROBE APPARATUS AND WAFER TRANSFER SYSTEM

(71) Applicant: TOKYO ELECTRON LIMITED, Tokyo (JP)

(72) Inventor: Yasuhiro OSUGA, Yamanashi (JP)

(73) Assignee: TOKYO ELECTRON LIMITED, Tokyo (JP)

(21) Appl. No.: 14/758,378

(22) PCT Filed: Dec. 12, 2013
(86) PCT No.: PCT/JP13/84000

§ 371 Date: Jun. 29, 2015

(30) Foreign Application Priority Data
Jan. 9, 2013 (JP) 2013-001998

(51) Int. Cl. G01R 31/26; G01R 1/067; G03F 7/20

(52) U.S. Cl. CPC G01R 31/2601; G03F 7/70866; G01R 1/067

(57) ABSTRACT

The present disclosure provides a probe apparatus that is capable of suppressing generation of a transfer error by adsorbing and holding a semiconductor wafer even in a case where the semiconductor wafer has been warped. The probe apparatus includes a measuring section and a loader section, that is, a transfer unit. The loader section is provided with a wafer cassette placed on a load port, a wafer transfer mechanism having a wafer transfer arm, and a gas ejection mechanism having a gas ejection nozzle. When the wafer transfer arm adsorbs and holds a warped semiconductor wafer in the wafer cassette, the gas ejection nozzle ejects a gas from a substantially central portion on the upper side of the semiconductor wafer toward the lower side, thereby reducing warpage of the semiconductor wafer.

### TECHNICAL FIELD

The present disclosure relates to a probe apparatus and a wafer transfer system.

### BACKGROUND

In a semiconductor device manufacturing process, a probe apparatus has been used to perform an electrical inspection of a semiconductor device formed on a semiconductor wafer. There is known a probe apparatus which includes a measuring section that performs an electric measurement by bringing a probe into contact with the semiconductor device formed on the semiconductor wafer placed on a placing table, a load port on which a wafer carrier (wafer cassette or FOUP) is placed, and a wafer transfer unit having a transfer mechanism that transfers the semiconductor wafer between the wafer carrier and the placing table, in which the transfer mechanism is provided with a wafer transfer arm (see, e.g., Patent Document 1). Further, in the conventional probe apparatus, the semiconductor wafer is vacuum-sucked on the wafer transfer arm and transferred.

### PRIOR ART DOCUMENT

### Patent Document

Patent Document 1: Japanese Patent Laid-Open Publication No. 2008-235845

### SUMMARY OF THE INVENTION

### Problems to be Solved

However, when the semiconductor wafer is warped, the semiconductor wafer cannot be vacuum-sucked, resulting in a transfer error which causes the probe apparatus to stop. Such a problem that the probe apparatus stops due to the warpage of the semiconductor wafer, is expected to be aggravated, for example, by the thinning of the semiconductor wafer, which proceeds as a demand for power semiconductors increases.

An object of the present disclosure is to provide a probe apparatus and a wafer transfer system, which may suppress generation of a transfer error by sucking and holding a semiconductor wafer even in a case where the semiconductor wafer is warped.

### Means to Solve the Problems

In order to solve the aforementioned problem, according to an aspect, the present disclosure provides a probe apparatus for performing an electric measurement of a semiconductor device formed on a semiconductor wafer on a placing table. The probe apparatus includes a measuring section configured to perform the electric measurement by bringing a probe into contact with the semiconductor device of the semiconductor wafer placed on the placing table; a load port on which a wafer carrier accommodating the semiconductor wafer is placed; a wafer transfer mechanism provided with a suction unit that vacuum-sucks the semiconductor wafer, and configured to transfer the semiconductor wafer between the wafer carrier and the placing table; and a gas ejection mechanism configured to spray a gas to an upper surface of the semiconductor wafer when the semiconductor wafer accommodated in the wafer carrier is vacuum-sucked to the suction unit.

In the present disclosure, the gas ejection mechanism may be configured to spray the gas to a central portion of the semiconductor wafer.

In the present disclosure, the gas ejection mechanism may be provided with a nozzle that ejects the gas. A base end portion of the nozzle may be fixed by a rotation driving mechanism that pivots the nozzle between a standby position where the whole nozzle is not present above the semiconductor wafer and a gas ejection position where a front end portion of the nozzle is positioned above the semiconductor wafer.

In order to solve the aforementioned problem, according to another aspect, the present disclosure provides a wafer transfer system including a load port on which a wafer carrier accommodating a semiconductor wafer is placed; a wafer transfer mechanism provided with a suction unit that vacuum-sucks the semiconductor wafer, and configured to transfer the semiconductor wafer between the wafer carrier and the placing table; and a gas ejection mechanism configured to spray a gas to an upper surface of the semiconductor wafer when the semiconductor wafer accommodated in the wafer carrier is vacuum-sucked to the suction unit.

In the present disclosure, the gas ejection mechanism may be configured to spray the gas to a central portion of the semiconductor wafer.

In the present disclosure, the gas ejection mechanism may be provided with a nozzle that ejects the gas. A base end portion of the nozzle may be fixed by a rotation driving mechanism that pivots the nozzle between a standby position where the whole nozzle is not present above the semiconductor wafer and a gas ejection position where a front end portion of the nozzle is positioned above the semiconductor wafer.

### Effect of the Invention

According to the present disclosure, a semiconductor wafer may be sucked and held even in a case where the semiconductor wafer is warped. Therefore, generation of a transfer error may be suppressed.

### BRIEF DESCRIPTION OF THE DRAWINGS

FIG. 1 is a schematic plan view illustrating a configuration of a probe apparatus according to an exemplary embodiment of the present disclosure.

FIG. 2 is a schematic front view illustrating a configuration of a loader section in FIG. 1.

FIG. 3A is a view used for explaining a standby position where the whole gas ejection nozzle of FIG. 2 is not present above a semiconductor wafer.

FIG. 3B is a view used for explaining a gas ejection position where a front end portion of the gas ejection nozzle of FIG. 2 is positioned above the central portion of the semiconductor wafer.

FIG. 4 is a flowchart illustrating an air assist processing procedure of ejecting the gas from the gas ejection nozzle of FIG. 3B toward the semiconductor wafer.

FIG. 5 is a plan view illustrating a modified embodiment of the transfer arm of FIGS. 3A and 3B.

FIG. 6 is a view used for explaining a method of vacuum-sucking a semiconductor wafer using the transfer arm.

### DETAILED DESCRIPTION TO EXECUTE THE INVENTION

Hereinafter, exemplary embodiments of the present invention will be described in detail with reference to the accompanying drawings.

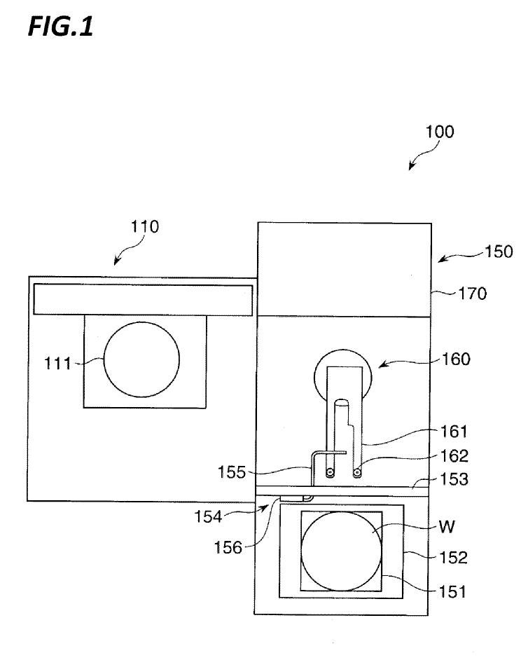

FIG. 1 is a schematic plan view illustrating a configuration of a probe apparatus according to an exemplary embodiment of the present disclosure.

A probe apparatus 100 of FIG. 1 includes a measuring section 110 and a loader section 150 as a transfer unit. The measuring section 110 is movable back and forth, left and right, or up and down, and is provided with a placing table 111 on which a semiconductor wafer W is placed. The measuring section 110 brings probes provided on a probe card (not illustrated) into contact with the electrodes of a plurality of semiconductor devices formed on the semiconductor wafer W to measure electric characteristics of the semiconductor devices.

The loader section 150 includes a load port 152 in which a wafer cassette 151 as a wafer carrier accommodating the semiconductor wafer W is placed, at its front side (lower side in FIG. 1). In addition, the loader section 150 includes a wafer transfer mechanism 160 provided adjacent to the load port 152. The loader section 150 further includes a positioning mechanism 170 at its rear side (upper side in FIG. 1). The positioning mechanism 170 rotates the semiconductor wafer W to detect a notch position of the semiconductor wafer W and a status of the eccentricity of the semiconductor wafer W.

The wafer transfer mechanism 160 includes a wafer transfer arm 161 that vacuum-sucks and transfers the semiconductor wafer W. The wafer transfer arm 161 includes a plurality of (two in the present exemplary embodiment) suction units (suction pads) 162 that vacuum-suck the semiconductor wafer W. Each suction unit 162 is connected with a vacuum line (not illustrated in FIG. 1) connected to a suction source such as a vacuum pump. Further, a plurality of wafer transfer arms 161 may be provided to be vertically stacked.

The wafer transfer mechanism 160 transfers the semiconductor wafer W among the wafer cassette 151 placed on the load port 152, the positioning mechanism 170, and the placing table 111 of the measuring section 110 by the back-and-forth, left-and-right, or up-and-down movement and pivoting of the wafer transfer arm 161.

The load port 152 is freely moved up and down by an up-and-down moving mechanism (not illustrated). A support frame 153 is provided between the load port 152 and the wafer transfer mechanism 160, and includes an optical detector (not illustrated). And, the optical detector detects the presence of the semiconductor wafer W while moving the wafer cassette 151 placed on the load port 152 up and down by moving the load port 152 up and down, and detects a slot in the wafer cassette 151 where the semiconductor wafer W is placed.

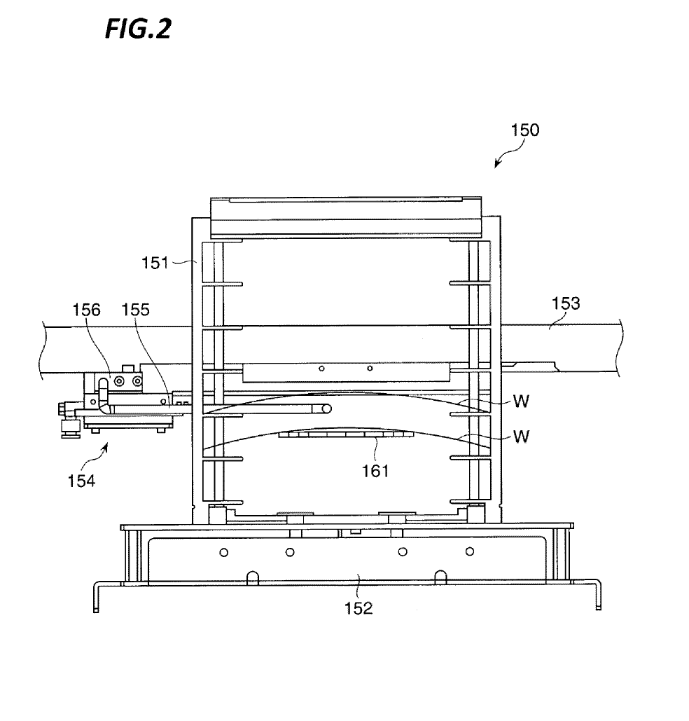

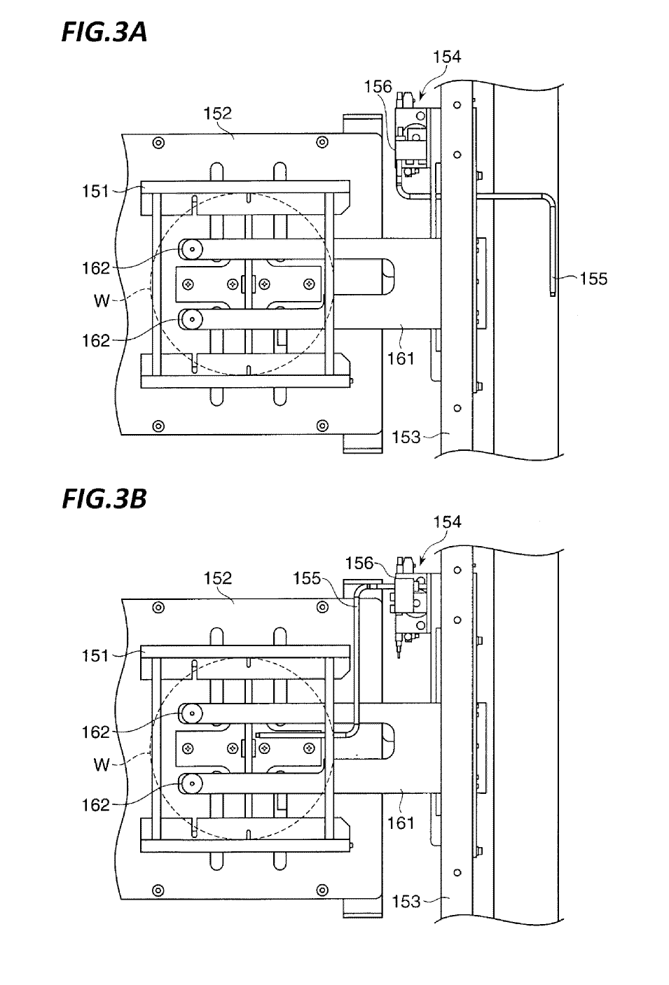

Further, the support frame 153 includes a gas ejection mechanism 154. The gas ejection mechanism 154 includes a gas ejection nozzle 155 formed of a pipe-shaped member (FIG. 2 and FIGS. 3A and 3B). The base end portion of the gas ejection nozzle 155 is fixed to a rotation driving mechanism 156 (to be described below) provided in the support frame 153. The rotation driving mechanism 156 may pivot the gas ejection nozzle 155 about the base end portion of the gas ejection nozzle 155 fixed to the rotation driving mechanism 156, between a standby position where the whole gas ejection nozzle 155 is not present above the semiconductor wafer W (FIG. 3A) and a gas ejection position where a front end portion of the gas ejection nozzle 155 is positioned above the central portion of the semiconductor wafer (FIG. 3B).

In the present exemplary embodiment, the wafer cassette 151 has a configuration capable of accommodating a warped semiconductor wafer W, as illustrated in FIG. 2, and its slot interval is set to be wider than, for example, about 5 to 6 times the conventional wafer cassette (a slot pitch of, for example, about 23 mm to 29 mm). Further, the number of slots is set to be smaller than that of the conventional wafer cassette, for example, about 6 to 8.

When the warped semiconductor wafer W in the wafer cassette 151 is adsorbed and held by the wafer transfer arm 161 of the transfer mechanism 160, a gas (air in the present exemplary embodiment) is ejected from a substantially central portion of the upper side (upper surface) of the semiconductor wafer W toward the lower side by the gas ejection nozzle 155, as illustrated in FIG. 2 and FIG. 3B, such that the central portion of the semiconductor wafer W is pressed downwardly by the pressure of the gas to reduce the warpage of the semiconductor wafer W, thereby adsorbing the semiconductor wafer W onto the wafer transfer arm 161.

Specifically, as illustrated in FIG. 2, when the semiconductor wafer W whose central portion is warped toward the upper side in a convex shape is intended to be sucked and held by the wafer transfer arm 161 from the lower side of the semiconductor wafer W, a gap is generated between the suction unit 162 of the wafer transfer arm 161 and the rear surface of the semiconductor wafer W. Therefore, the semiconductor wafer W cannot be vacuum-sucked. Accordingly, in the present exemplary embodiment, the gas ejection nozzle 155 ejects the gas from the substantially central portion of the semiconductor wafer W toward the lower side, so that the wafer transfer arm 161 vacuum-sucks the semiconductor wafer W in a state where the central portion of the semiconductor wafer W is pressed by the pressure of the gas. As a result, the wafer transfer arm 161 is capable of vacuum-sucking the semiconductor wafer W in a state where the warpage of the semiconductor wafer W is substantially reduced. Therefore, a semiconductor wafer W warped in a higher proportion may be sucked and held.

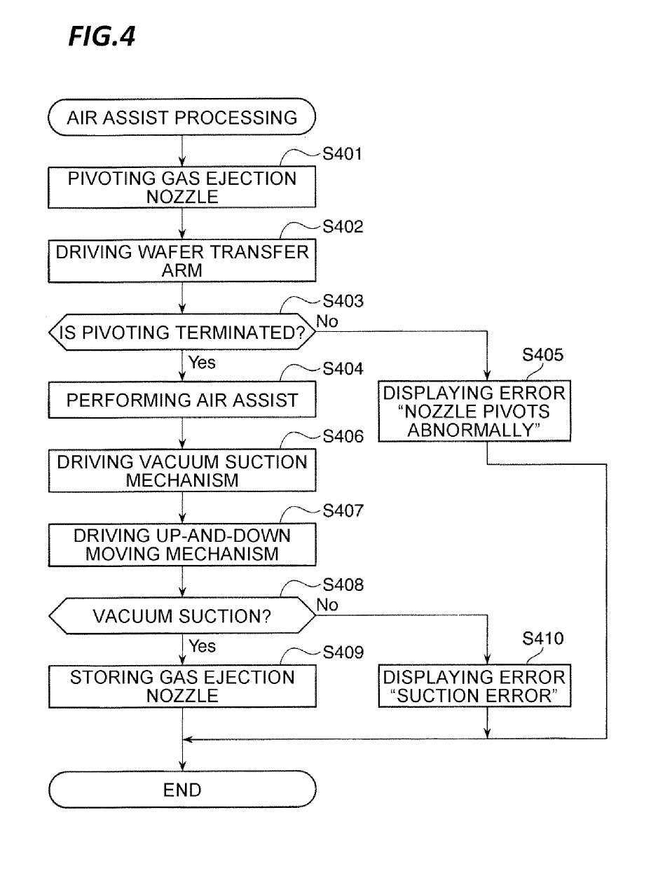

FIG. 4 is a flowchart illustrating an air assist processing procedure of ejecting the gas from the gas ejection nozzle 155 of FIG. 3B toward the semiconductor wafer W.

In FIG. 4, the rotation driving mechanism 156 pivots the gas ejection nozzle 155 positioned at the standby position (FIG. 3A) to position the front end portion of the gas ejection nozzle to the gas ejection position above the central portion of the semiconductor wafer W (step S401). The wafer transfer mechanism 160 drives the wafer transfer arm 161 to be inserted into the lower side of the semiconductor wafer W (step S402).

Next, the gas ejection mechanism 154 determines whether the pivoting of the gas ejection nozzle 155 is completed (step S403). As a result of the determination in step S403, when the pivoting of the gas ejection nozzle 155 is completed (Yes in step S403), the gas is ejected from the gas ejection nozzle 155 toward the semiconductor wafer W (hereinafter, referred to as “air assist”) (step S404).

Meanwhile, when the pivoting of the gas ejection nozzle 155 is not completed (No in step S403), an error indication of “nozzle pivots abnormally” is displayed, for example, on a display device (not illustrated) connected to the outside of the probe apparatus 100 (step S405), and the present processing is terminated.

In the following step S406, a vacuum suction mechanism, which includes a suction source such as a vacuum pump connected to the suction unit 162 provided in the wafer transfer arm 161 through a vacuum line (not illustrated), is driven. Subsequently, the up-and-down moving mechanism of the load port 152 is driven to move down the wafer cassette 151 (step S407), and the wafer transfer arm 161 vacuum-sucks the semiconductor wafer W.

Subsequently, the rotation driving mechanism 156 determines whether the semiconductor wafer W is vacuum-sucked onto the wafer transfer arm 161 (step S408). As a result of the determination in step S408, when the semiconductor wafer W is vacuum-sucked (Yes in step S408), the gas ejection nozzle 155 is pivoted to return to the standby position (step S409), and the present processing is terminated.

Meanwhile, when the semiconductor wafer W is not vacuum-sucked, an error indication of “suction error” is displayed, for example, on a display device (not illustrated) connected to the outside of the probe apparatus 100 (step S410), and the present processing is terminated.

In the probe apparatus 100 having the aforementioned configuration, when the wafer cassette 151 accommodating the semiconductor wafer W whose central portion is warped toward the upper side in a convex shape is placed on the load port 152 of the loader section 150, the up-and-down moving mechanism of the load port 152 is driven such that the wafer cassette 151 moves up and down, and the optical detector detects the slots in the wafer cassette 151 accommodating the semiconductor wafer W.

Next, the wafer transfer arm 161 performs air assist using the gas ejection nozzle 155 provided in the gas ejection mechanism 154 to vacuum-suck the semiconductor wafer W having reduced warpage, which is then transferred to the positioning mechanism 170. Then, the positioning mechanism 170 detects the position of the semiconductor wafer W by detecting the notch of the semiconductor wafer W.

Subsequently, the wafer transfer arm 161 takes out the semiconductor wafer W whose position is detected by the positioning mechanism 170 from the positioning mechanism 170 and places the semiconductor wafer W on the placing table 111.

Then, the semiconductor wafer W on the placing table 111 is inspected about electric characteristics by bringing the probes of the probe card into contact with the semiconductor devices of the semiconductor wafer W. Specifically, the electric characteristic inspection of the semiconductor devices is performed by supplying test signals from a tester (not illustrated) to the semiconductor devices and measuring output signals output to the tester from the semiconductor devices.

When the electric characteristic inspection of the semiconductor devices of the semiconductor wafer W is terminated, the wafer transfer arm 161 accommodates the semiconductor wafer W on the placing table 111 in the wafer cassette 151.

That is, according to the processing in FIG. 4, since the air assist is performed to eject the gas toward the semiconductor wafer W (step S404), the wafer transfer arm 161 may suck and hold the semiconductor wafer W having reduced warpage, and thus, generation of a transfer error may be suppressed.

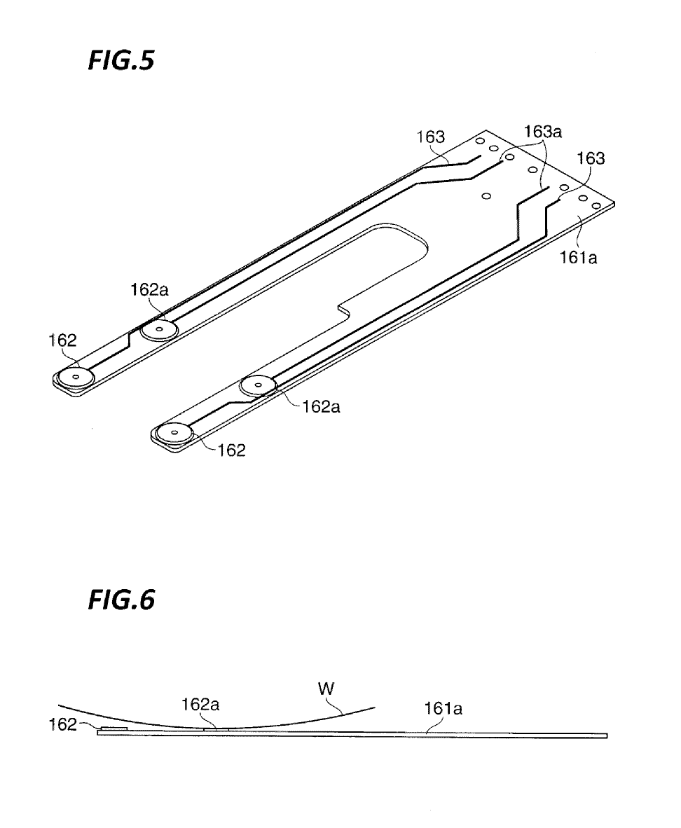

In the present exemplary embodiment, descriptions have been made on a case of vacuum-sucking the semiconductor wafer W whose central portion is warped toward the upper side in a convex shape. On the contrary to this, however, in a case of vacuum-sucking a semiconductor wafer W whose central portion is warped toward the lower side in a concave shape, a transfer arm 161a having a configuration illustrated in FIG. 5 may be used. That is, the wafer transfer arm 161a illustrated in FIG. 5 includes two more suction units 162a at the rear end side in the length direction in addition to the two suction units 162 of the transfer arm 161 illustrated in FIG. 1 and FIGS. 3A and 3B. Therefore, there are four suction units 162, 162a in total. Further, each suction unit 162 is connected with a vacuum line 163 and each suction unit 162a is connected with a vacuum line 163a. Therefore, the vacuum suction of the suction units 162 and the suction units 162a may be independently performed.

When the wafer transfer arm 161 a having the aforementioned configuration is used, for example, as illustrated in FIG. 6, even in a case where the semiconductor wafer W whose central portion is warped toward the lower side in a concave shape cannot be vacuum-sucked only with the suction units 162 at the front end side, the wafer transfer arm 161a may suck and hold the semiconductor wafer W by vacuum suction of the suction units 162a at the rear end side vacuum-adsorb the semiconductor wafer W. Further, as the semiconductor wafer W is vacuum-sucked onto the suction units 162a at the rear end side, the semiconductor wafer W is also vacuum-sucked onto the suction units 162 at the front end side. In this case, the semiconductor wafer W is vacuum-sucked by both of the suction units 162a at the rear end side and the suction units 162 at the front end side. Further, in a case where any one of the suction units 162a at the rear end side and the suction units 162 at the front end side vacuum-sucks the semiconductor wafer W, it is possible to drive only the vacuum suction mechanism including the suction units which are vacuum-sucking.

The present disclosure has been described with reference to exemplary embodiments, but various modifications may be made without being limited to the above-mentioned exemplary embodiments. For example, the measuring section of the probe apparatus 100 may be connected with an external apparatus, or the present disclosure may be a wafer transfer system configured as an apparatus which realizes the functions of the aforementioned exemplary embodiments with the external apparatus.

This application is based on and claims priority from Japanese Patent Application No. 2013-001998, filed on Jan. 9, 2013 with the Japan Patent Office, the disclosures of which is incorporated herein in its entirety by reference.

### DESCRIPTION OF SYMBOL

100: probe apparatus
110: measuring section
111: placing table
150: loader section
151: wafer cassette
152: load port
153: support frame
154: gas ejection mechanism
155: gas ejection nozzle
156: rotation driving mechanism
160: wafer transfer mechanism
161: wafer transfer arm
162: suction unit
170: positioning mechanism

1. A probe apparatus for performing an electric measurement of a semiconductor device formed on a semiconductor wafer on a placing table, the apparatus comprising:
a measuring section configured to perform the electric measurement by bringing a probe into contact with the semiconductor device of the semiconductor wafer placed on the placing table;
a load port on which a wafer carrier accommodating the semiconductor wafer is placed;
a wafer transfer mechanism provided with a plurality of suction units that vacuum-suck the semiconductor wafer, and configured to transfer the semiconductor wafer between the wafer carrier and the placing table;
a gas ejection mechanism configured to spray a gas to an upper surface of the semiconductor wafer when the semiconductor wafer accommodated in the wafer carrier is vacuum-sucked to the suction unit; and
a support frame to which the gas ejection mechanism is attached,
wherein:
the gas ejection mechanism includes a nozzle that ejects the gas,
a base end portion of the nozzle is fixed by a rotation driving mechanism that pivots the nozzle between a standby position where the whole nozzle is not present above the semiconductor wafer and a gas ejection position where a front end portion of the nozzle is positioned above the semiconductor wafer,
the gas ejection mechanism is attached to the support frame through the rotation driving mechanism,
the wafer carrier accommodates multiple semiconductor wafers to be stacked,
the load port moves in the stacking direction of the multiple semiconductor wafers;
the nozzle enters between the multiple semiconductor wafers which are stacked, and
each of the plurality of suction units is connected with an independent vacuum line, and each of plurality of suction units independently performs vacuum suction.

2. The probe apparatus of claim 1, wherein the wafer transfer mechanism is configured as a transfer arm, and when the transfer arm transfers the semiconductor wafer, each of the plurality of suction units faces an end portion or a central portion of the semiconductor wafer when viewing the transfer arm vertically with respect to the transfer direction of the semiconductor wafer from a lateral side of the transfer arm.

3. (canceled)

4. A wafer transfer system comprising:
a load port on which a wafer carrier accommodating a semiconductor wafer is placed;
a wafer transfer mechanism provided with a plurality of suction units that vacuum-suck the semiconductor wafer, and configured to transfer the semiconductor wafer between the wafer carrier and the placing table;
a gas ejection mechanism configured to spray a gas to an upper surface of the semiconductor wafer when the semiconductor wafer accommodated in the wafer carrier is vacuum-sucked to the suction unit; and
a support frame to which the gas ejection mechanism is attached,
wherein:
the gas ejection mechanism includes a nozzle that ejects the gas,
a base end portion of the nozzle is fixed by a rotation driving mechanism that pivots the nozzle between a standby position where the whole nozzle is not present above the semiconductor wafer and a gas ejection position where a front end portion of the nozzle is positioned above the semiconductor wafer,
the gas ejection mechanism is attached to the support frame through the rotation driving mechanism,
the wafer carrier accommodates multiple semiconductor wafers to be stacked,
the load port moves in the stacking direction of the multiple semiconductor wafers,
the nozzle enters between the multiple semiconductor wafers which are stacked, and
each of the plurality of suction units is connected with an independent vacuum line, and each of the plurality of suction units independently performs vacuum suction.

5. The wafer transfer system of claim 4, wherein the wafer transfer mechanism is configured as a transfer arm, and when the transfer arm transfers the semiconductor wafer, each of the plurality of suction units faces an end portion or a central portion of the semiconductor wafer when viewing the transfer arm vertically with respect to the transfer direction of the semiconductor wafer from a lateral side of the transfer arm.

6. (canceled)
